(19) United States
(12) Patent Application Publication
(10) Pub. No.: US 2025/0283911 A1
(43) Pub. Date: Sep. 11, 2025

(54) PROBE UNIT AND CONTACT PROBE

(71) Applicant: NHK Spring Co. Ltd., Yokohama-shi (JP)

(72) Inventors: Kazuya Soma, Kanagawa (JP); Ryohei Inohara, Kanagawa (JP); Naruhiko Nishiwaki, Kanagawa (JP)

(73) Assignee: NHK Spring Co. Ltd., Yokohama-shi (JP)

(21) Appl. No.: 19/068,080

(22) Filed: Mar. 3, 2025

(30) Foreign Application Priority Data
Mar. 8, 2024 (JP) 2024-035755

(51) Int. Cl. G01R 1/073; G01R 1/067

(52) U.S. Cl. CPC G01R 1/07307; G01R 1/06722

(57) ABSTRACT

A probe unit includes: a plurality of probe groups each including two contact probes configured to come into contact with one electrode of a contact target; and a probe holder configured to hold the contact probes. Each of the two contact probes includes: a distal end portion; and a flange portion extending from a proximal end side of the distal end portion and having a maximum length in a direction orthogonal to a longitudinal axis of the contact probe larger than a maximum length of the distal end portion, the flange portion including a first flat surface portion having a planar shape provided on a part of a side surface of the flange portion, and the holder hole has a stepped shape configured to be locked by the flange portion and has a wall surface abutting on the first flat surface portion.

This application is based upon and claims the benefit of priority of the prior Japanese Patent Application No. 2024-035755, filed on Mar. 8, 2024, the entire contents of which are incorporated herein by reference.

### BACKGROUND

The present disclosure relates to a probe unit and a contact probe used for conduction state inspection or operation characteristic inspection of an inspection target such as a semiconductor integrated circuit or a liquid crystal panel.

In the replated art, when conduction state inspection or operation characteristic inspection of an inspection object such as a semiconductor integrated circuit or a liquid crystal display device is performed, a conductive contact probe that electrically connects the inspection target and a signal processing device having a circuit board that outputs an inspection signal is used. As one of the above-described conduction state inspection and operation characteristic inspection methods, there is a four-terminal measurement method. As a probe unit using this four-terminal measurement method, a technique is disclosed in which a distal end of each contact probe is brought into contact with an inspection target to measure an electrical characteristic by a set of contact probes (probe group) held by a probe holder (see, for example, JP 2021-105550 A).

### SUMMARY

In the technique disclosed in JP 2021-105550 A, in order to prevent the contact probe from rotating with respect to the probe holder, the distal end portion is formed in a flat plate shape, and the flat surface portion is brought into contact with the holder. For this reason, the volume of the distal end portion is smaller than that of other portions, and there is a problem that durability is deteriorated due to repetition of inspection or the like.

There is a need for a probe unit and a contact probe capable of securing strength of the contact probe while suppressing rotation with respect to a probe holder.

According to one aspect of the present disclosure, there is provided a probe unit including: a plurality of probe groups each including two contact probes configured to come into contact with one electrode of a contact target on one end portion side in a longitudinal direction, each of the two contact probes coming into contact with a different electrode of a substrate on another end portion side; and a probe holder configured to hold the contact probes, the probe holder including a plurality of holder holes configured to hold the plurality of contact probes, wherein each of the two contact probes includes: a distal end portion configured to come into contact with the one electrode of the contact target at a distal end; and a flange portion extending from a proximal end side of the distal end portion and having a maximum length in a direction orthogonal to a longitudinal axis of the contact probe larger than a maximum length of the distal end portion, the flange portion including a first flat surface portion having a planar shape provided on a part of a side surface of the flange portion, and the holder hole has a stepped shape configured to be locked by the flange portion and has a wall surface abutting on the first flat surface portion.

According to another aspect of the present disclosure, there is provided a contact probe for coming into contact with one electrode of a contact target on one end portion side in a longitudinal direction, the contact probe including: a distal end portion configured to come into contact with the one electrode of the contact target at a distal end; and a flange portion extending from a proximal end side of the distal end portion and having a maximum length in a direction orthogonal to a longitudinal axis of the contact probe larger than a maximum length of the distal end portion, the flange portion including a flat surface portion having a planar shape provided on a part of a side surface of the flange portion.

### BRIEF DESCRIPTION OF THE DRAWINGS

FIG. 1 is a perspective view illustrating a configuration of a probe unit according to an embodiment;

FIG. 2 is a partial cross-sectional view illustrating a configuration of a main portion of a probe unit according to the embodiment;

FIG. 3 is a partial cross-sectional view illustrating a configuration of a main portion of a probe unit according to the embodiment;

FIG. 4 is a view illustrating a configuration of a first plunger and a probe holder viewed from a direction of an arrow A in FIG. 3;

FIG. 5 is a view for explaining a configuration of a first plunger according to a first modification;

FIG. 6 is a view for explaining a configuration of a first plunger according to a second modification;

FIG. 7 is a perspective view (part 1) for explaining a configuration of a probe according to a third modification; and

FIG. 8 is a perspective view (part 2) for explaining a configuration of the probe according to the third modification.

### DETAILED DESCRIPTION

Hereinafter, embodiments will be described in detail with reference to the drawings. Note that the present disclosure is not limited by the following embodiments. In addition, the drawings referred to in the following description merely schematically illustrate shapes, sizes, and positional relationships to the extent that the contents of the present disclosure may be understood. That is, the present disclosure is not limited only to the shape, size, and positional relationship illustrated in each drawing.

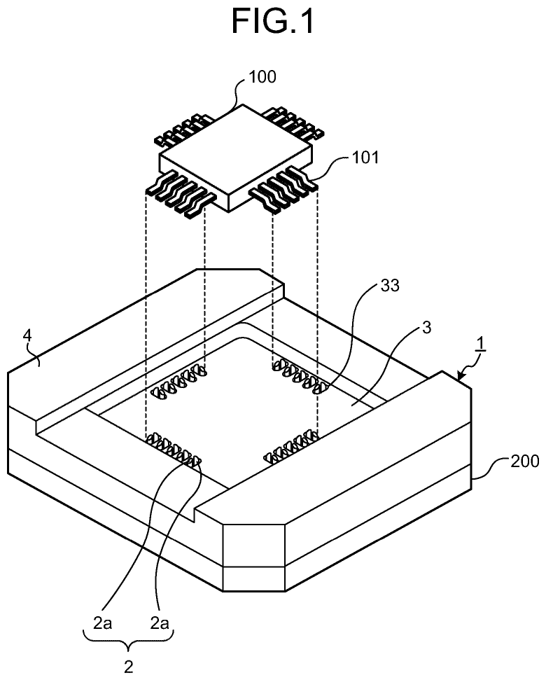

FIG. 1 is a perspective view illustrating a configuration of a probe unit according to an embodiment. A probe unit 1 illustrated in FIG. 1 is a device used when an electrical characteristic inspection of a semiconductor integrated circuit as an inspection object is performed, and is a device that electrically connects a connection electrode of a semiconductor package 100 enclosing the semiconductor integrated circuit and a circuit board 200 that outputs an inspection signal to the semiconductor integrated circuit. The connection electrode of the semiconductor package 100 is a lead 101 illustrated in FIG. 1 and is connected to a semiconductor integrated circuit.

A probe unit 1 includes: a probe holder 3 that includes a plurality of probe groups 2 including two contact probes 2a (hereinafter, simply referred to as “probe 2a”) that each come into contact with one connection electrode (lead 101) of a semiconductor package 100 that is a contacted body on one end portion side in a longitudinal direction and comes into contact with different electrodes of a circuit board 200 on the other end portion side, and accommodates and holds the plurality of probe groups 2 according to a predetermined pattern; and a holder member 4 that is provided around the probe holder 3 and suppresses occurrence of positional deviation of the semiconductor package 100 that comes into contact with the plurality of probe groups 2 at the time of inspection.

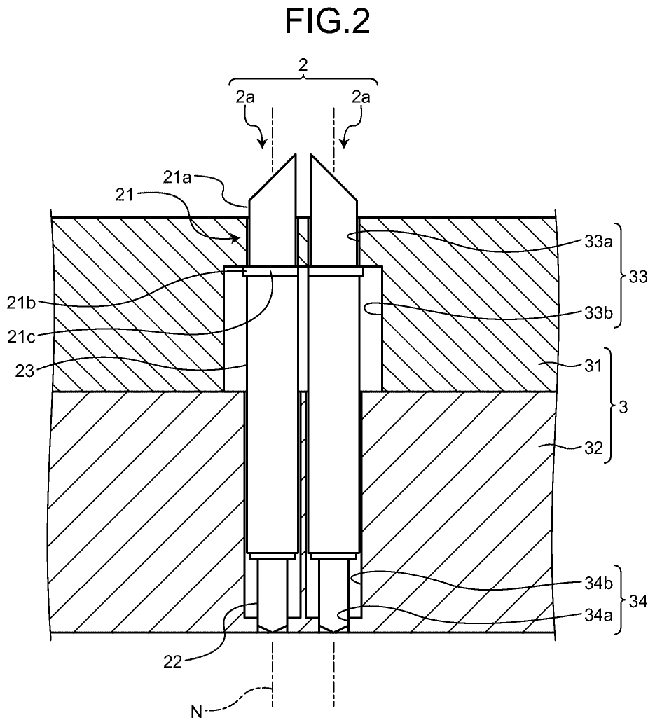

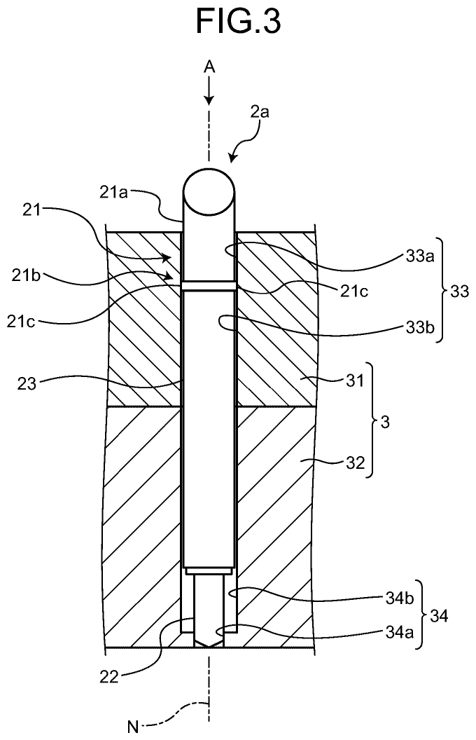

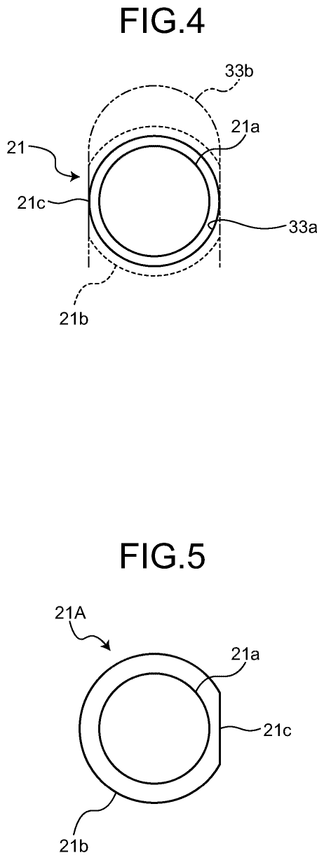

FIG. 2 is a partial cross-sectional view illustrating a configuration of a main portion of a probe unit according to an embodiment. FIG. 3 is a partial cross-sectional view illustrating a configuration of a main portion of a probe unit according to an embodiment. FIG. 4 is a view illustrating a configuration of a first plunger and a probe holder viewed from a direction of an arrow A in FIG. 3. FIG. 2 is a partial cross-sectional view illustrating a detailed configuration of the probe group 2 accommodated in the probe holder 3, and is a cross sectional view taken along a flat surface parallel to an arrangement direction of the probe group 2. FIG. 3 is a partial cross-sectional view illustrating a detailed configuration of the probe group 2 accommodated in the probe holder 3, and is a cross sectional view taken along a flat surface orthogonal to an arrangement direction of the probe group 2. In the probe group 2 illustrated in FIGS. 2 and 3, two probes 2a formed using a conductive material are arranged in parallel so as to have the same height. In addition, the probe groups 2 are arranged according to the arrangement of the connection electrodes (leads 101) of the semiconductor package 100.

The probe 2a includes a first plunger 21 that comes into contact with the lead 101 of the semiconductor package 100 when the semiconductor integrated circuit is inspected, a second plunger 22 that comes into contact with the electrode of the circuit board 200 including the inspection circuit, and a barrel 23 to which the first plunger 21 is attached at one end and to which the second plunger 22 is extendably coupled at the other end. The first plunger 21 and the second plunger 22 constituting the probe 2a, and the barrel 23 have the same axis (here, the axis N). The axis N corresponds to the longitudinal axis of the probe 2a.

The first plunger 21 has a columnar distal end portion 21a in which a flat surface inclined with respect to the axis is formed, and a flange portion 21b extending from the proximal end side of the distal end portion 21a, at least a part of which has a larger length in a direction orthogonal to the axis than the distal end portion 21a, substantially coaxially. The first plunger 21 has a stepped shape at a connection portion between the distal end portion 21a and the flange portion 21b. Note that the first plunger 21 is attached to the barrel 23 by fitting, welding, or the like.

Note that “the same axis” and “coaxially” include manufacturing errors or the like.

The distal end portion 21a has an inclined surface obliquely cut with respect to the axis N direction, and is in contact with the lead 101 of the semiconductor package 100 at the distal end.

The distal end portion 21a has a cylindrical shape except for the distal end portion. That is, in the distal end portion 21a, a portion other than the contact portion with the lead 101 forms a columnar shape without a notch, and the volume of the distal end portion 21a is secured.

Note that the distal end portion 21a may have any shape that may come into contact with the lead 101, such as a crown shape or a cylindrical shape.

The flange portion 21b has two flat surface portions 21c formed by cutting a part of a side surface into a planar shape. The two flat surface portions 21c are provided on opposite sides to each other with respect to the axis of the flange portion 21b. Note that the axis of the flange portion 21b is an axis extending in parallel with the axis of the first plunger 21 and passing through the center of gravity, and coincides with the axis of the first plunger 21 here.

In the present embodiment, the flat surface portion 21c is provided on the side portion side of the inclined surface of the distal end portion 21a.

Note that the flat surface portion 21c may have an uneven shape at a plurality of locations in the circumferential direction to such an extent that the flat surface portion 21c may come into contact with the wall surface of the probe holder 3. That is, in the present embodiment, the “flat surface” of the flat surface portion 21c includes a flat surface having surface roughness that allows contact with the wall surface of the probe holder 3 at a plurality of positions.

The second plunger 22 has a columnar shape having a tapered distal end shape. The second plunger 22 is in contact with a coil spring in the barrel 23 or is provided with a flange or the like to be prevented from coming off from the barrel 23.

A coil spring is provided inside the barrel 23 to bias the second plunger 22. When the semiconductor package 100 is brought into contact with the probe 2a, the second plunger 22 moves in the axis direction with respect to the barrel 23 to relieve an impact on the connection electrode of the semiconductor package 100, and applies a load to the semiconductor package 100 and the circuit board 200 by the biasing force of the coil spring in the barrel 23.

The probe holder 3 is formed using an insulating material such as resin, machinable ceramic, or silicon, and is formed by laminating a first member 31 located on the upper surface side and a second member 32 located on the lower surface side in FIG. 2. A holder hole including a first hole portion 33 and a second hole portion 34 for accommodating the plurality of probes 2a is formed in the first member 31 and the second member 32. The formation position of the holder hole is determined according to the wiring pattern of the semiconductor package 100. At this time, for example, the probe group 2 is arranged such that the distal end sides of the distal end portions 21a of the probes 2a approach each other.

Both the first hole portion 33 and the second hole portion 34 have stepped hole shapes having different diameters along the penetration direction. That is, the first hole portion 33 has an opening in the upper end surface of the probe holder 3, and includes two small diameter portions 33a through which the distal end portions 21a of the probes 2a passes, and a large diameter portion 33b having a diameter larger than those of the small diameter portions 33a and through which the two probes 2a pass. The small diameter portion 33a is slightly larger than the diameter of the distal end portion 21a and smaller than the maximum length of the flange portion 21b. In addition, the large diameter portion 33b has a long hole shape capable of accommodating the two probes 2a, and the shortest length is equal to or slightly larger than the distance between the flat surface portions 21c of the flange portion 21b.

On the other hand, the second hole portion 34 includes a small diameter portion 34a having an opening in the lower end surface of the probe holder 3 and a large diameter portion 34b having a diameter larger than that of the small diameter portion 34a. The small diameter portion 34a has a diameter slightly larger than the diameter of the second plunger 22. In addition, the large diameter portion 34b has a diameter slightly larger than the diameter of the barrel 23. The second hole portion 34 accommodates the probe 2a. For this reason, in the probe group 2, the probes 2a are respectively accommodated in the through-holes in which the two second hole portions 34 are connected to the large diameter portion 33b with respect to the first hole portion 33 having the two small diameter portions 33a and the large diameter portion 33b. The shapes of the first hole portion 33 and the second hole portion 34 are determined according to the configuration of the probe 2a to be accommodated. Note that the large diameter portion 34b through which the probes 2a forming a set are inserted may be a common hole portion having no wall surface.

The flange portion 21b of the first plunger 21 abuts on a boundary wall surface between the small diameter portion 33a and the large diameter portion 33b of the first hole portion 33, thereby having a function of preventing the probe 2a from coming out of the probe holder 3 (see FIG. 2). At this time, the flat surface portion 21c abuts on a wall surface (here, a flat surface part of the long hole shape) of the large diameter portion 33b or faces the wall surface with a slight gap (see FIG. 4). For this reason, when a force rotating around the axis N is applied to the probe 2a, the flat surface portion 21c abuts on the wall surface of the large diameter portion 33b, whereby the rotation around the axis N is suppressed.

During the inspection of the semiconductor integrated circuit, the inspection signal supplied from the circuit board 200 to the semiconductor integrated circuit reaches the lead 101 of the semiconductor package 100 from the electrode of the circuit board 200 via the probes 2a. Specifically, the probe 2a reaches the lead 101 of the semiconductor package 100 via the second plunger 22, the barrel 23, and the first plunger 21. Note that, in the two electrodes of the circuit board 200, for example, one electrode is a measurement electrode (Sense), and the other electrode is a power transmission electrode (Force).

In addition, since the distal end of the distal end portion 21a is formed to be tapered, even in a case where an oxide film is formed on the surface of the lead 101, the oxide film may be broken through, and the distal end of the distal end portion 21a may be brought into direct contact with the lead 101.

According to the above-described embodiment, in the flange portion 21b of the columnar first plunger 21, two planar flat surface portions 21c are formed, and the flat surface portions 21c abut on the wall surface of the hole of the probe holder 3 (here, the wall surface of the large diameter portion 33b). Therefore, by controlling the rotation of the probe 2a around the axis while securing the volume of the distal end portion 21a, it is possible to secure the strength of the contact probe while suppressing the rotation with respect to the probe holder.

In addition, according to the present embodiment, since the small diameter portion 33a has a round hole shape and regulates the position of the distal end portion 21a, a change in the distance between the distal end portions 21a of the probes 2a forming a pair is suppressed, and as a result, the positionability of the probe 2a may be improved.

Next, a first modification of the present embodiment will be described with reference to FIG. 5. FIG. 5 is a view for explaining a configuration of a first plunger according to a first modification. Note that the same components as the components described above in FIG. 2 or the like are denoted by the same reference numerals. In the above-described embodiment, it has been described that two flat surface portions 21c are provided in the flange portion 21b, but in the present first modification, one flat surface portion 21c is formed.

In a first plunger 21A according to the first modification, one flat surface portion 21c is provided in the flange portion 21b, and the flat surface portion 21c is brought into contact with the wall surface of the hole of the probe holder 3, whereby the rotation of the probe 2a around the axis may be controlled.

According to the above-described first modification, similarly to the above-described embodiment, in the flange portion 21b of the columnar first plunger 21, one planar flat surface portion 21c is formed, and the flat surface portion 21c abuts on the wall surface of the hole of the probe holder 3. Therefore, by controlling the rotation of the probe 2a around the axis while securing the volume of the distal end portion 21a, it is possible to secure the strength of the contact probe while suppressing the rotation with respect to the probe holder.

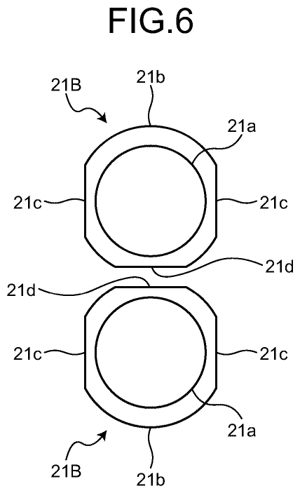

Next, a second modification of the present embodiment will be described with reference to FIG. 6. FIG. 6 is a view for explaining a configuration of a first plunger according to a second modification. Note that the same components as the components described above in FIG. 2 or the like are denoted by the same reference numerals. In the second modification, the flange portion 21b is further provided with a second flat surface portion 21d.

In a first plunger 21B according to the second modification, the flange portion 21b includes the second flat surface portion 21d provided at a position different from the first flat surface portion 21c in addition to the flat surface portion 21c (in the second modification, the first flat surface portion 21c). The second flat surface portion 21d is provided between the flat surface portions 21c in the circumferential direction and has a planar shape. Note that the second flat surface portion 21d is provided at a portion facing the other probe 2a forming a set when installed in the probe holder 3.

When the probe 2a is installed in the probe holder 3, the second flat surface portion 21d of the probes 2a face each other. At this time, since the rotation of the probes 2a is regulated by the first flat surface portion 21c, the probes 2a may be brought close to each other to such an extent that the second flat surface portions 21d do not come into contact with each other.

According to the above-described second modification, similarly to the above-described embodiment, in the flange portion 21b of the columnar first plunger 21, two planar flat surface portions 21c are formed, and the flat surface portions 21c abut on the wall surface of the hole of the probe holder 3. Therefore, by controlling the rotation of the probe 2a around the axis while securing the volume of the distal end portion 21a, it is possible to secure the strength of the contact probe while suppressing the rotation with respect to the probe holder.

In addition, according to the second modification, since the second flat surface portions 21d of the probes 2a are arranged to face each other, it is possible to narrow the pitch between the probes 2a as compared with the configuration according to the embodiment.

Note that, in the second modification, the configuration of the first modification may be adopted, and a configuration including one first flat surface portion 21c may be adopted.

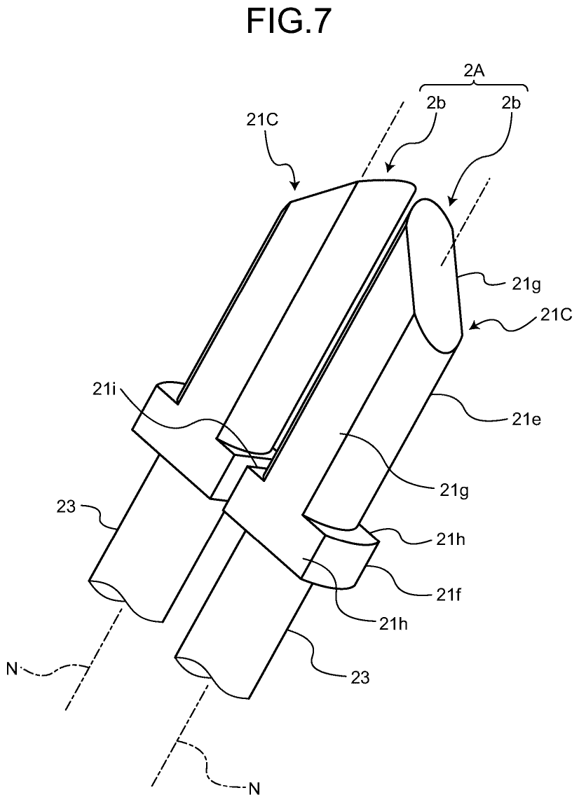

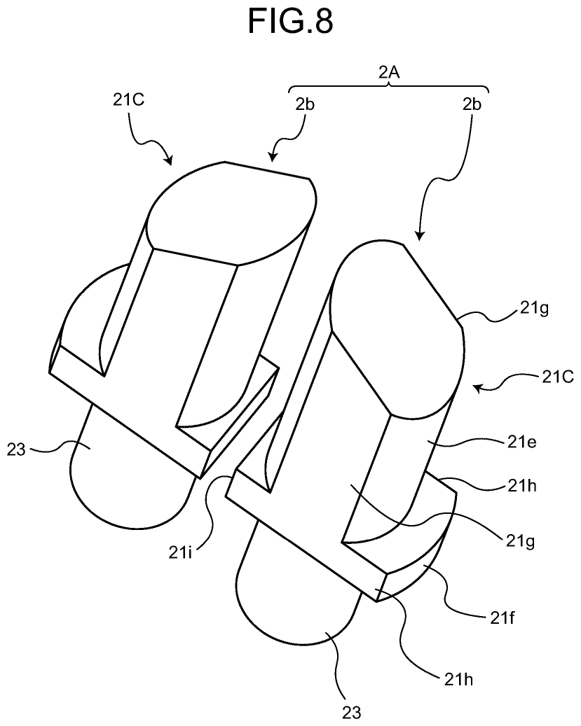

Next, a third modification of the present embodiment will be described with reference to FIGS. 7 and 8. FIGS. 7 and 8 are perspective views for explaining a configuration of the probe according to the third modification. FIGS. 7 and 8 are perspective views of the probe as viewed from different directions. Note that the same components as the components described above in FIG. 2 or the like are denoted by the same reference numerals. In the third modification, a probe group 2A is provided instead of the probe group 2 according to the embodiment. Note that, in FIGS. 7 and 8, only a part of the probe is illustrated.

In the probe group 2A, two probes 2b formed using a conductive material are arranged in parallel so as to have the same height. In addition, the probe groups 2A are arranged according to the arrangement of the connection electrodes (leads 101) of the semiconductor package 100.

The probe 2b includes a first plunger 21C that comes into contact with the lead 101 of the semiconductor package 100 when the semiconductor integrated circuit is inspected, a second plunger 22 (see FIG. 2 or the like) that comes into contact with the electrode of the circuit board 200 including the inspection circuit, and a barrel 23 to which the first plunger 21C is attached at one end and to which the second plunger 22 is extendably coupled at the other end. The first plunger 21C and the second plunger 22 constituting the probe 2b, and the barrel 23 have the same axis (here, the axis N).

The first plunger 21C has a columnar distal end portion 21e in which a flat surface inclined with respect to the axis is formed, and a flange portion 21f extending from the proximal end side of the distal end portion 21e, at least a part of which has a larger length in a direction orthogonal to the axis than the distal end portion 21e, substantially coaxially. The first plunger 21C has a stepped shape at a connection portion between the distal end portion 21e and the flange portion 21f. Note that the first plunger 21C is attached to the barrel 23 by fitting, welding, or the like.

The distal end portion 21e has an inclined surface obliquely cut with respect to the axis N direction at the distal end, and is in contact with the lead 101 of the semiconductor package 100 at the distal end.

In addition, the distal end portion 21e has two flat surface portions 21g forming a flat surface parallel to the axis N direction. The two flat surface portions 21g are provided on the side portions of the inclined surface at the distal end, and are provided on the opposite sides to each other with the axis N interposed therebetween.

The flange portion 21f includes two first flat surface portions 21h obtained by cutting a part of a side surface in a planar shape, and a second flat surface portion 21i provided at a position different from the first flat surface portion 21h. The two first flat surface portions 21h are provided on opposite sides to each other with respect to the axis of the flange portion 21b. The second flat surface portion 211 is provided between the first flat surface portions 21h in the circumferential direction.

In the third modification, the first flat surface portion 21h is provided on the side of the inclined surface of the distal end portion 21a.

Note that, similarly to the flat surface portion 21c, the first flat surface portion 21h and the second flat surface portion 21i may have an uneven shape at a plurality of locations in the circumferential direction to the extent that the first flat surface portion 21h and the second flat surface portion 21i may contact the wall surface of the probe holder 3.

In the third modification, one flat surface portion 21g forms a flat surface portion flush with one first flat surface portion 21h, and the other flat surface portion 21g forms a flat surface portion flush with the other first flat surface portion 21h.

When the probe 2b is installed in the probe holder 3, the second flat surface portion 211 of the probes 2b face each other. At this time, since the rotation of the probes 2b is regulated by the flat surface portion 21g and the first flat surface portion 21h, the probes 2b may be brought close to each other to such an extent that the second flat surface portion 21i do not come into contact with each other.

In the third modification, by providing the flat surface portion 21g forming the same plane as the first flat surface portion 21h and securing the arrangement region in the direction orthogonal to the direction in which the flat surface portion 21g faces, it is possible to secure the volume of the distal end portion 21e while securing the function of regulating the rotation of the probe by the first flat surface portion 21h of the flange portion 21f.

According to the above-described third modification, similarly to the above-described embodiment, in the flange portion 21f of the columnar first plunger 21C, two planar first flat surface portions 21h are formed, and the first flat surface portions 21h abut on the wall surface of the hole of the probe holder 3. Therefore, by controlling the rotation of the probe 2b around the axis while securing the volume of the distal end portion 21e, it is possible to secure the strength of the contact probe while suppressing the rotation with respect to the probe holder.

Furthermore, according to the third modification, since the flat surface portion 21g continuous with the first flat surface portion 21h is formed at the distal end portion 21e of each probe 2b, the range having the function of regulating the rotation of the probe 2b around the axis may be expanded, and the rotation of the probe 2b around the axis may be regulated more reliably.

In addition, according to the third modification, since the second flat surface portion 211 of the probes 2a are arranged to face each other, it is possible to narrow the pitch between the probes 2b as compared with the configuration according to the embodiment.

Although the embodiments for carrying out the present disclosure have been described so far, the present disclosure should not be limited only by the above-described embodiments. The (first) flat surface portion and the second flat surface portion are not limited to those shown in the above-described embodiment and modification, and the setting of the formation range of the flat surface portion in the flange portion and the like may be appropriately changed. In addition, the flat surface portion may be formed outside the position where the flange portion is connected to the distal end portion. That is, at the flat surface portion forming position, a stepped shape in which the flange portion side protrudes from the distal end portion to the flange portion is formed.

In addition, the probe 2a used for the probe group 2 is not limited to the above-described one including the plunger and the barrel as long as it has a flange portion, and may be one including the above-described plunger and coil spring having a distal end portion, or a pogo pin. In addition, the connection electrode may have a hemispherical shape in addition to a flat plate shape such as the lead 101.

As described above, the probe unit and the contact probe according to the present disclosure are useful for ensuring the strength of the contact probe while suppressing the rotation with respect to the probe holder.

According to the present disclosure, it is possible to secure the strength of the contact probe while suppressing the rotation with respect to the probe holder.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiments have been described in detail, it should be understood that the various changes, substitutions, and alterations could be made hereto without departing from the spirit and scope of the disclosure.

What is claimed is:

1. A probe unit comprising:
a plurality of probe groups each including two contact probes configured to come into contact with one electrode of a contact target on one end portion side in a longitudinal direction, each of the two contact probes coming into contact with a different electrode of a substrate on another end portion side; and
a probe holder configured to hold the contact probes, the probe holder including a plurality of holder holes configured to hold the plurality of contact probes,
wherein each of the two contact probes includes:
a distal end portion configured to come into contact with the one electrode of the contact target at a distal end; and
a flange portion extending from a proximal end side of the distal end portion and having a maximum length in a direction orthogonal to a longitudinal axis of the contact probe larger than a maximum length of the distal end portion, the flange portion including a first flat surface portion having a planar shape provided on a part of a side surface of the flange portion, and
the holder hole has a stepped shape configured to be locked by the flange portion and has a wall surface abutting on the first flat surface portion.

2. The probe unit according to claim 1, wherein the first flat surface portion includes two flat surfaces provided on opposite sides to each other with respect to the longitudinal axis.

3. The probe unit according to claim 1, wherein the first flat surface portion is constituted of one flat surface.

4. The probe unit according to claim 1, wherein the flange portion includes a second flat surface portion facing another one of the two contact probes at a position different from the first flat surface portion in a state where the two contact probes are installed in the probe holder.

5. A contact probe for coming into contact with one electrode of a contact target on one end portion side in a longitudinal direction, the contact probe comprising:
a distal end portion configured to come into contact with the one electrode of the contact target at a distal end; and
a flange portion extending from a proximal end side of the distal end portion and having a maximum length in a direction orthogonal to a longitudinal axis of the contact probe larger than a maximum length of the distal end portion, the flange portion including a flat surface portion having a planar shape provided on a part of a side surface of the flange portion.
